(19) United States
(12) Patent Application Publication
(10) Pub. No.: US 2026/0204868 A1
(43) Pub. Date: Jul. 16, 2026

(54) VERTICAL CAVITY SURFACE-EMITTING LASER DEVICES

(71) Applicant: MELLANOX TECHNOLOGIES, LTD., Yokneam (IL)

(72) Inventors: Filip Leonard Hjort, Partille (SE); Yuri Berk, Haifa (IL); Vladimir Iakovlev, Vaud (CH); Anders Larsson, Hovas (SE); Isabelle Cestier, Haifa (IL); Elad Mentovich, Tel Aviv (IL); Petter Westbergh, Gothenburg (SE)

(21) Appl. No.: 19/022,495

(22) Filed: Jan. 15, 2025

(51) Int. Cl. H01S 5/065; H01S 5/00; H01S 5/10; H01S 5/183

(52) U.S. Cl. CPC H01S 5/0651; H01S 5/0085; H01S 5/1021; H01S 5/18394

(57) ABSTRACT

Approaches presented herein provide for the emission of a selected wavelength of light from a laser device, such as a transverse-coupled cavity, vertical cavity surface-emitting laser (TCC VCSEL) devices, through use of one or more mode filters. Feedback from at least one secondary cavity can be used to overcome intrinsic bandwidth limitations of a VCSEL device, where the performance can be strongly dependent on feedback parameters such as strength, phase, and time constant. The mode filter can be used to stabilize and provide controllability of the wavelength for single mode operation. The TCC VCSEL may have one or more intracavity implantations to confine current and one or more contacts configured to reduce electrical resistance.

### TECHNICAL FIELD

This disclosure relates to laser devices, and in particular to a mode filter, intracavity implantations, and contacts for vertical cavity surface-emitting laser devices.

### BACKGROUND

Various networking and communication-based environments take advantage of optical communication mechanisms, such as may rely on generated and/or modulated laser light. The laser light can be generated using various types of laser-emitting devices, such as vertical cavity surface-emitting laser (VCSEL) devices. VCSELs are used extensively in optical transceivers and interconnects due to benefits such as their high-speed modulation and beam properties, low production cost, and low power consumption. As bitrates per lane continue to increase-moving to 200 Gb/s and beyond-it is becoming increasingly challenging for VCSELs to meet the bandwidth requirements of approximately 40 GHz or higher. One typical approach to increasing VCSEL bandwidth is to increase the resonance frequency by biasing at higher current or modifying the VCSEL design, but such approaches are bounded by reliability constraints or physics and fabrication limitations. An approach to obtain bandwidths beyond that of a conventional VCSEL is to couple light from two different cavities. The cavities can be fabricated next to each other on the wafer such as may be transversely coupled to each other by connecting their optical apertures, creating so called transverse-coupled cavities (TCCs). Such a device can help breach the bandwidth limitation set by the individual VCSEL's resonance frequency by introducing a shift to higher frequencies or extra resonances in addition to the second order system. The modulation response of TCC VCSELs is exceptionally sensitive to the nature of the feedback, however, as may related to the feedback strength, phase, and time constant. Further, if a laser is multimode, with multiple transverse modes lasing at different wavelengths, the feedback and, in turn, the bandwidth may become unstable and unpredictable where small variations in, for example, ambient temperature or biasing could drastically alter the bandwidth. If there are many wavelengths, the effect from the different feedback components may also counteract and prevent the wanted bandwidth increase. It is possible to use lasers with very small apertures to achieve single-mode lasing, but these are harder to fabricate, have high electrical resistance, and low output power.

### BRIEF DESCRIPTION OF THE DRAWINGS

Various embodiments in accordance with the present disclosure will be described with reference to the drawings, in which:

FIG. 1A illustrates an example network architecture where laser devices can emit modulated light to be propagated across an array of optical fibers, according to at least one embodiment;

FIG. 1B illustrates a cross-section view of a TCC VCSEL with a mode filter, according to at least one embodiment;

FIG. 1C illustrates a cross view of VCSEL with intracavity implantations and contacts according to at least one embodiment;

FIG. 1D illustrates a cross view of VCSEL with intracavity implantations and contacts according to at least one embodiment;

FIG. 1E illustrates a cross view of VCSEL with intracavity implantations and contacts according to at least one embodiment;

FIG. 1F illustrates a cross view of VCSEL with intracavity implantations and contacts according to at least one embodiment;

FIG. 1G illustrates a cross view of VCSEL with intracavity implantations and contacts according to at least one embodiment;

FIG. 1H illustrates a cross view of VCSEL with intracavity implantations and contacts according to at least one embodiment;

FIG. 1I illustrates a cross view of VCSEL with intracavity implantations and contacts according to at least one embodiment;

FIG. 2A illustrates multiple and single mode propagation in coupled cavities, according to at least one embodiment;

FIG. 2B illustrates the optical response of a VCSEL without, and with, optical coupling between cavities, according to at least one embodiment;

FIG. 3A illustrates a top view of a TCC VCSEL with a mode filter, according to at least one embodiment;

FIG. 3B illustrates other example configurations that can be used with a single mode TCC VCSEL, according to at least one embodiment;

FIG. 3C illustrates an example configuration that can be used with a VCSEL, according to at least one embodiment;

FIG. 3D illustrates an example configuration that can be used with a VCSEL, according to at least one embodiment;

FIG. 3E illustrates an example configuration that can be used with a VCSEL, according to at least one embodiment;

FIG. 3F illustrates an example configuration that can be used with a VCSEL, according to at least one embodiment;

FIG. 4A illustrates an example process for emitting a single wavelength of light from a TCC VCSEL useful for optical communication, according to at least one embodiment;

FIG. 4B illustrates an example laser device, according to at least one embodiment;

FIG. 4C illustrates an example optical communication system, according to at least one embodiment;

FIG. 4D illustrates an example single mode, transverse-coupled cavity, vertical cavity surface-emitting laser, according to at least one embodiment;

FIG. 4E illustrates an example of a VCSEL that is able to function as an excitable laser in a photonics neural network, according to at least one embodiment;

FIG. 5 illustrates an example data center system, according to at least one embodiment;

FIGS. 6A and 6B illustrate a top view and a perspective view, respectively, of a transceiver module operatively coupled to a network adapter, in the present example a Network Interface Controller (NIC), according to at least one embodiment;

FIG. 7 illustrates an example system on chip integrated circuit, according to at least one embodiment;

FIG. 8 illustrates a computing system according to at least one embodiments; and

FIG. 9 illustrates a computing system according to at least one embodiment.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

Existing solutions for addressing bandwidth capacitance and related challenges in vertical cavity surface emitting lasers (VCSELs) have demonstrated significant limitations. For example, while ion implantation can effectively reduce capacitance by creating highly resistive regions within the VCSEL, such a process is hindered by practical issues such as the need for thick photoresist masks during implantation through extensive epitaxial distributed Bragg reflectors (DBRs). This not only complicates the definition of narrow structures due to lateral straggle but also leads to optical absorption and increased resistance when current must traverse these narrow, thick epitaxial areas. Additionally, relying solely on either implantation or oxide layer current confinement in intracavity contacts tends to result in elevated capacitance or resistance levels which undermine performance. Furthermore, the modulation response of transverse coupled cavity vertical cavity surface-emitting lasers (TCC VCSELs) is critically influenced by feedback parameters—strength, phase, and time constant—which are contingent on cavity geometry and lasing wavelength. In multimode scenarios where multiple transverse modes operate at varying wavelengths, feedback stability may become compromised. For example, even minor fluctuations in ambient conditions or biasing can unpredictably alter bandwidth. Although single-mode lasing offers advantages like reduced beam divergence and extended transmission distances, achieving this with small apertures introduces fabrication challenges alongside high electrical resistance and low output power. Collectively, these shortcomings highlight the inadequacies of conventional methods in effectively resolving bandwidth capacitance issues within VCSEL technology.

Approaches in accordance with various illustrative embodiments provide for selection of a one or more modes or wavelengths (or filtering of other modes or wavelengths) to be emitted by transverse coupled cavity vertical cavity surface-emitting laser (TCC VCSEL) devices. This may include, for example, a single mode or wavelength to be emitted, or a selection of a primary mode or wavelength if there are to be multiple modes or wavelengths used, whether concurrently, at separate times, and/or from separate cavities. Approaches presented herein also allow for the varying of modulation speed, including speed that were not previously achievable using at least certain laser devices. Such high speed modulation supports use of TCC VCSELs in devices such as optical transmitters and interconnects that require high data rate support, and can provide such speed with relatively low cost and complexity. A TCC VCSEL can include at least two cavities in which emitted light can reflect and lase. The cavities can be fabricated next to each other on a wafer, for example, and transversely couple to each other by connecting their optical apertures. A mode filter can be positioned with respect to at least a primary cavity in order to promote emission of a selected wavelength of light (or “mode”) from the TCC VCSEL. The selected wavelength can correspond to a wavelength that is to be used for optical communications, for example, such as a wavelength in the range of about 750 nm-1600 nm, or in the range of about 1000 nm-1100 nm for certain communication devices, among other such ranges and values. A mode filter can be selected that has an opening or transmissive region with an appropriate shape (e.g., circular) and lateral dimension (e.g., between half and a full diameter of an aperture of the primary cavity), as may be positioned centrally to the cavity and aligned with the aperture. In some embodiments, the entire mode filter can be formed of a transmissive material, or can form a transmissive region, such that the entire width of the region functions as a mode filter, such as where the mode filter is a region of a specific size and dimension(s) to “select” a specific wavelength of light. For an aperture with a diameter of around 5 microns, a corresponding mode filter might have a diameter in the range of about 2.5 microns to about 5.0 microns. A mode filter may be etched into a top layer of the VCSEL or added as a top layer, or intermediate layer, with the mode filter portion and surrounding layer portion having different thicknesses selected to promote reflections for the primary wavelength. The ability to couple light from at least two cavities can provide for higher bandwidth for uses in optical transceivers and interconnects, for example, while the mode filter promotes the lasing of a single, selected mode and allows for control of the feedback parameters to further increase or prevent unwanted variations in bandwidth. The ability to tightly control operational modes can be beneficial when, for example, a primary cavity receives optical feedback from a secondary cavity, as aspects of the feedback from the secondary cavity, such as wavelength and delay, when properly controlled can help breach the bandwidth limitation of the primary cavity through optimized coupling of the light from the primary cavity and at least one secondary cavity. One or more implantation steps can be performed to electrically isolate the cavities from each other, thereby increasing the controllability of the performance by separately tuning the bias point of the primary cavity and the strength and phase of the feedback. Such a device can be used advantageously for optical communication or computing, including use as an excitable laser in a photonics neural network, among other such operations.

The emitted laser light from a TCC VCSEL achieves higher bandwidth in an optical communication system through the combination of multiple cavities and the implementation of a mode filter. By utilizing at least two transversely coupled cavities, the TCC VCSEL can generate and reflect light that not only enhances the overall emission but also allows for coherent coupling between the cavities. This coupling enables the primary cavity to receive optical feedback from the secondary cavity, effectively improving the lasing conditions and introducing additional resonances or shifts to higher frequencies. The mode filter selectively promotes the emission of a specific wavelength or mode while minimizing unwanted modes, which helps stabilize and control the output. This control over operational modes reduces variations in bandwidth, allowing for faster modulation speeds as compared to traditional single-cavity lasers.

Variations of this and other such functionality can be used as well within the scope of the various embodiments as would be apparent to one of ordinary skill in the art in light of the teachings and suggestions contained herein.

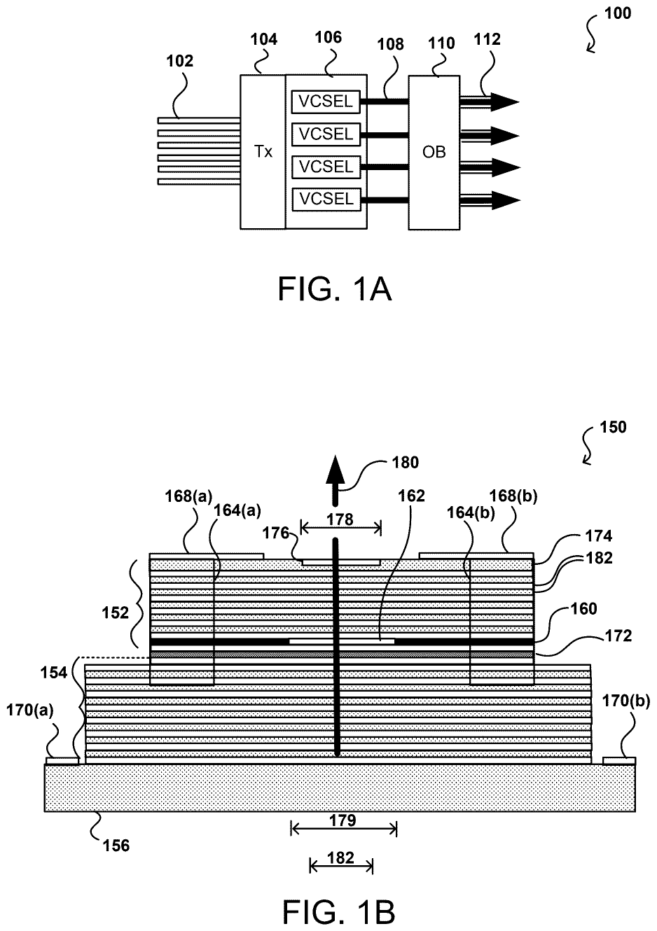

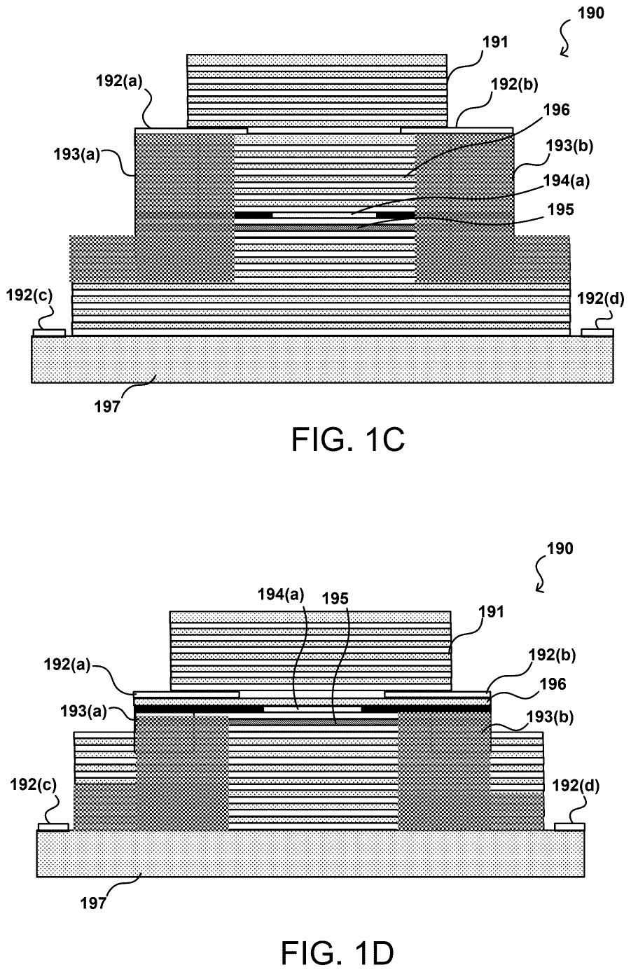

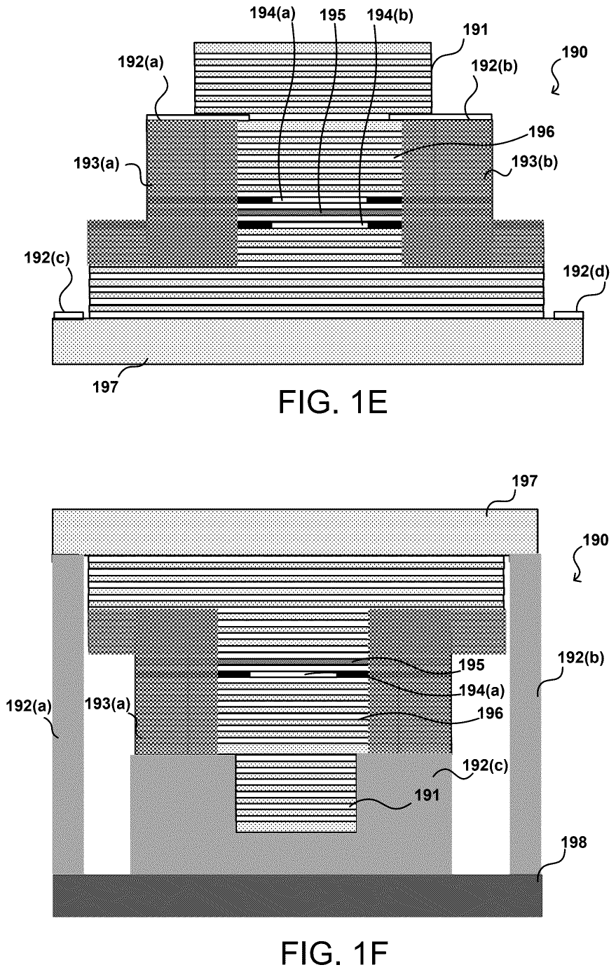

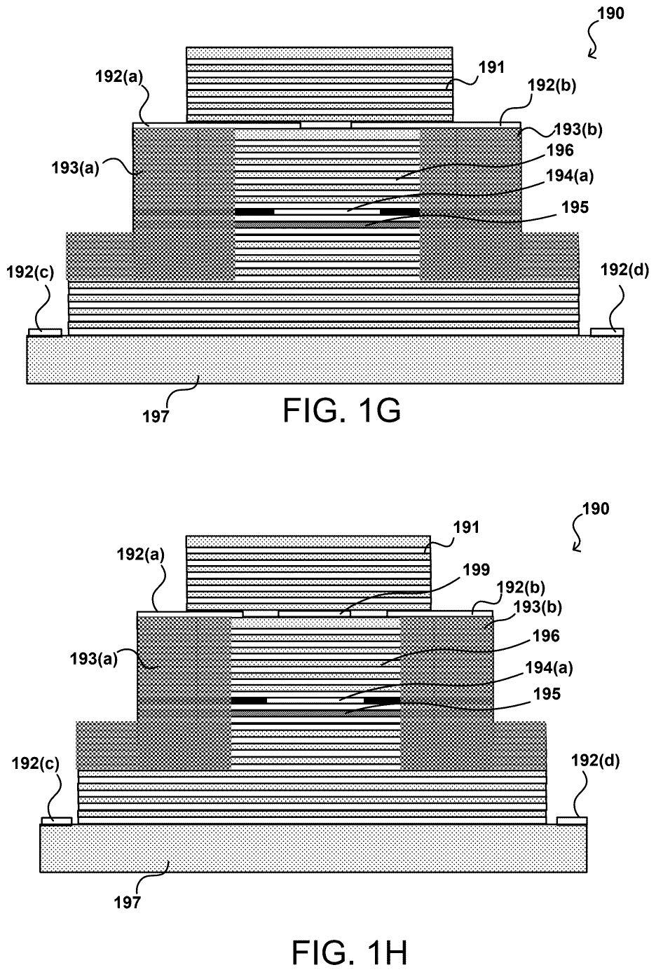

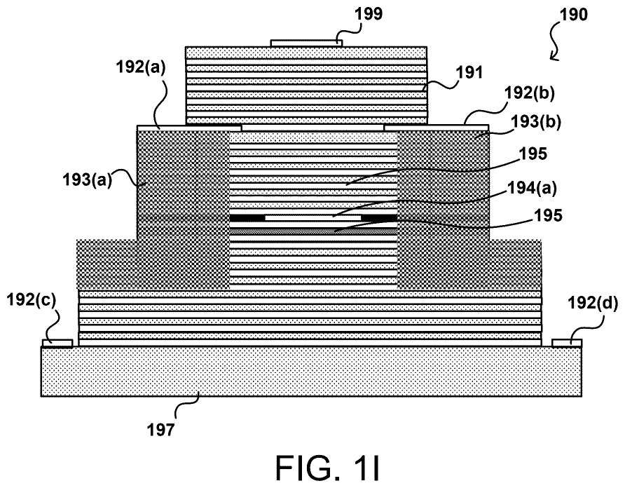

FIG. 1A illustrates an example transmitter implementation 100 that can be used for optical communications. In this example, there are multiple transmitters in a single device, although in other implementations each transmitter could be used as a separate device. In an optical communication network, data may be received in electronic or digital form to a set of input electrodes 102 that can then be processed by transmitting circuitry 104. The transmitting circuitry can cause one or more optical transmitters 106 to transmit optical signals 108 that encode the data that was received electronically. The optical signals 108 from the various transmitters 106 can be coupled or guided into respective optical fibers 112 for transmission. One or more optical elements (e.g., lenses), as may be part of an optical bench 110, can be used to couple, focus, or otherwise direct the output laser light from a respective transmitter into a respective fiber, although in some embodiments a fiber may be able to transmit signals from multiple transmitters. In some implementations, a VCSEL may also include at least one receiver photodiode and can then function as a transceiver that is also able to receive transmitted optical signals.

In the example of FIG. 1A, the optical transmitters 106 are to generate laser light using vertical-cavity surface-emitting lasers (VCSELs). VCSELs are used extensively in optical transmitters and interconnects due to benefits such as their high-speed modulation and beam properties, low production cost, and low power consumption. As mentioned, minimum bitrates per lane in optical communications is continually increasing, which as mentioned can be challenging for conventional VCSEL devices. One approach that can be used to reach bandwidths beyond that of a conventional VCSEL is to couple light from two or more cavities. Such cavities can be fabricated in a number of ways, such as by forming cavities next to each other on a wafer and transversely coupling the cavities to each other by connecting their optical apertures. Such devices are generally referred to as transverse-coupled cavity (TCC), or TCC VCSELs. The TCC VCSEL devices can be modelled either as two lasing cavities coherently coupled to each other, or as a primary cavity receiving optical feedback from a secondary cavity after a certain time delay, among other such options. In such cases, the feedback received from the coupling can help breach the bandwidth limitation set by the resonance frequency of an individual VCSEL by, for example, introducing a shift to higher frequencies or extra resonances in addition to the second order system.

FIG. 1B illustrates a cross-section of an example TCC VCSEL 150 in accordance with at least one embodiment. This device includes multiple layers of material that form an upper and a lower distributed Bragg reflector (DBR). A DBR has a reflective structure formed from layers of alternative material with different refractive index, or variation of another such characteristic, resulting in periodic variation in effective refractive index, resulting in a plurality of effectively reflective layers 182. The use of upper and lower DBR regions allows these regions to function as p-type and n-type regions of a PN junction, for example, allowing the VCSEL to function as a type of semiconductor laser diode device. In this example, there is an active region 172 positioned centrally between the p-DBR region 152 and the n-DBR region 154 of layers. An aperture 162 placed in layer 160 in this example is positioned towards the bottom of the P-DBR region, close to the active region 172. Light generated in the VCSEL will be caused to reflect between the various layers, in a direction that is primarily vertical in the figure, or orthogonal to the primary planar arrangement of the DBR layers. Laser light 180 can then be emitted in a first direction from the TCC VCSEL 150. Although not visible in this cross-sectional view (but as illustrated in subsequent figures), the generated light can also reflect within at least one secondary cavity as discussed in more detail elsewhere herein.

In at least one embodiment, at least one mode filter 176 can be used in such a TCC VCSEL device 150, such as is illustrated in FIG. 1B. Such a mode filter 176 can help to provide improved control of the performance of a TCC VCSEL by promoting lasing of a single mode. An example spatial mode filter can be constructed such that the optical losses of a specific transverse mode, typically the fundamental mode, are lower than for other modes. In at least one embodiment, this can be performed by etching away part of an anti-phase layer 174 at the top of the epitaxial structure to generate an inverted mode filter. A top layer may have a greater thickness to provide for an amount of anti-reflection, and etching a mode filter down into this top layer can allow the thickness corresponding to the mode filter region to return to the reflection thickness, as the mode filter will not be etched all the way through the top layer in this example. Such an approach provides for the promoting of reflection in the area of the mode filter and reduced reflection elsewhere, which can help promote lasing of the mode that is mostly confined to the center of the aperture. In some embodiments, a layer of dielectric material could then be deposited or formed over the VCSEL after etching to provide for a layer of additional protection. Other types or placements of a mode filter can be used as well, such as to form a mode filter in the p-DBR layer 152 or at the aperture 162. Placing (or forming) a mode filter at a top layer of the VCSEL 150 can be performed for convenience, as etching a top layer may be less complicated than forming a mode filter in a middle layer of a p-DBR material, etc. An advantage of using such a mode filter on a transverse-cavity VCSEL is that the filter will promote only one lasing wavelength, and in turn only one angle of lateral propagation in the secondary cavity. Operating wavelengths of such a device can be in the range of about 750 nm-1600 nm, or in the range of about 1000 nm-1100 nm for certain devices, among other such options.

Such an approach can also allow for optimum control of the feedback parameters, and can help to prevent unwanted jumps in bandwidth due to mode switching or limited bandwidth increases due to counteracting feedback effects. One or more contacts 168(a), 168(b), 170(a), 170(b) can be used to provide electric current, and one or more components used to block or confine current where appropriate. For example, metal contacts can be used to inject current separately into the main circular cavity and/or at the edge of the secondary cavity, which can allow for different biasing conditions in the cavities helping to tune the feedback to achieve a target feedback pattern. In at least one embodiment, one or more implantation steps can be performed to electrically isolate the cavities from each other. Isolation through use of one or more insulating regions 164(a), 164(b) can help to further increase the controllability of the performance by separately tuning the bias point of the primary cavity, as well as the strength and phase of the feedback. Single-mode lasing achieved by using such a mode filter can also provide for smaller beam divergence, provide for improved control of the polarization of emitted light, and support longer transmission distances, among other such benefits.

When conventional VCSELs are in operation, the VCSEL may produce a significant amount of heat. The DBR layers (e.g., the p-DBR layers, n-DBR layers, etc.) within the VCSELs are poor conductors, so dissipating or managing this heat can be a challenge. Various VCSELs described herein include intracavity implantations, contacts, and apertures which, compared to conventions VCSELs, achieve a higher bandwidth and an improved thermal performance. More specifically, the implementation of the disclosure enables VCSELs to achieve high bandwidth and low heat dissipation by means of intracavity contacts and implantations, combined with a separate secondary current confinement dimension with a deeper extent, to simultaneously achieve low resistance and capacitance. These contacts and implantations may be extended to TCC VCSELs described elsewhere herein to provide an additional boost to the intrinsic bandwidth. Furthermore, the integration of these implantations and contacts may enable optical transceivers at higher bitrates than previously as well as low pJ/bit co-packed optics VCSEL solutions.

The intracavity implantations include implanted regions inserted within the cavity of the VCSELs. The implanted regions may be made of various materials, including without limitation thin epitaxial p-DBR layers, as well as any additional DBR layers. The intracavity implanted regions may be doped with one or more impurities or ion elements according to various example embodiments. The intracavity implantations confine and control the current within the VCSELs which allows for further customization of the device performance. By positioning the implantation within the cavity of the VCSEL, the needed implantation energy to penetrate the epitaxial DBR is reduced. As a result, straggle may be reduced, and the VCSEL may experience sharper lateral profiles, lower resistance and absorption, and lower capacitance. In example embodiments, the intracavity implantations may restrict the current in VCSELs to within the space defined by the implantations themselves. In other words, the current stays more narrowly within the space defined by the implantations. As a result, the total capacitance present in the VCSEL is reduced. In example embodiments, this reduction in capacitance may be in addition to the primary confinement of the current by the oxidation process that is usually used for the configuration of the aperture (e.g., sharply defined and low optical loss) as described elsewhere herein. In example embodiments, the shallow location of the implantations (e.g., just below or near the top layer of the VCSEL), may also allow for more efficient annealing out of optically absorbing defects. In concert with the aperture which also confines current during use of the VCSEL, these implantations provide an improvement over conventional VCSELs.

Additionally, the intracavity contacts described herein may significantly reduce the number of potential barriers that the holes need to pass, resulting in low electrical resistance even when used with relatively small diameter non-implanted regions. By reducing the resistance present in the VCSEL, the heat present in the VCSEL is reduced and thermal performance is improved, thereby improving high-speed modulation performance and reducing any interference or damage caused by excess heat. In some example embodiments, the reduction of the number of p-DBR pairs in the VCSEL will lead to less free carrier absorption, thereby reducing optical losses. As the free carrier absorption increases with temperature, this will be of extra importance for high temperature operation of the VCSELs. Additionally, having metal contacts closer to the aperture and junction area where most heat dissipation occurs enables more efficient heat extraction and thereby lower junction temperatures. The contacts may also be used to promote lasing of the fundamental mode over higher order modes due to the large optical field strength inside the VCSEL cavity, allowing for single-mode lasing for more stable and better control of the optical coupling between the transverse cavities that could be used for longer reach interconnects.

In example embodiments, the VCSEL can include many different embodiments as illustrated at least in FIGS. 1C-1I. Each of the example embodiments of FIGS. 1C-1I may include a VCSEL 190, one or more dielectric DBR layers 191, one more metal contacts 192(a), 192(b), 192(c), and 192(d), one or more intracavity implantations 193(a) and 193(b), one or more optical apertures 194(a) and 194(b) positioned above and below an active region layer 195, a substrate 197, and one or more n-DBR layers below the active region 195.

Generally, the VCSEL 190 may be used in a variety of systems, with lasing wavelengths in the range of 750-1600 nm, including pluggable transceivers, co-packaged optics on, or close to, the electronics, large 2-dimensional arrays of emitters, and neuron-like building blocks in compact neuromorphic photonics computing platforms. Depending on the nature of integration, the VCSELs may be top or bottom-emitting. The VCSEL 190 may include some or all of the elements including inter alia direct thermal connections, for example metal, between the intracavity contacts and the VCSEL substrate, heat sink, carrier, driver electronic integrate circuit (EIC) or printed circuit board (PCB), described with further reference to FIGS. 1A and 1B.

FIG. 1C illustrates a view of a VCSEL 190 with a first cavity and one or more apertures 194(a) and 194(b) to generate laser light to be emitted in a first direction, one or more intracavity implantations 193(a) and 193(b) positioned within the first cavity configured to confine current within the first cavity and one or more metal contacts 192(a), 192(b), 192(c), and 192(d) configured to reduce electrical resistance within the VCSEL 190.

In FIG. 1C, the VCSEL 190 is designed with a limited number of epitaxial p-DBR pairs 196. However, the number of epitaxial p-DBR pairs can vary. This can be optimized to find a balance between vertical and lateral resistance, optical absorption, implantation straggle and, in the case of mode filtering, mode suppression. Furthermore, the aperture may be defined by lateral selective oxidation, of one or several different layers positioned in the p and/or n-DBR, by properly choosing the semiconductor compositions in the epitaxial DBR, or by a tunnel junction, or by a combination thereof. In some example embodiments, in a tunnel junction aperture region, the p-type region (layer) may be disposed between a multi-quantum well (MQW) layer stack and the tunnel junction. In still other example embodiments, the tunnel junction may comprise a heavily doped p++/n++ indium aluminum gallium arsenide tunnel junction, such that it defines an optical aperture for laser light emitted by the VCSEL. In still other example embodiments, the aperture may be defined in an oxide confinement layer between the tunnel junction and Multi-Quantum well and/or dots Layers (MQL) of VCSEL gain media stack. In still other embodiments, a portion of the to-be-oxidized layer may not be oxidized such that a non-oxidized portion of a confinement layer provides and/or defines an aperture through enabling electrical and/or optical flux therethrough. the case of multiple apertures, they may have different diameters, see FIG. 1c. In the case of using a tunnel junction, the p-DBR can be replaced by a n-DBR, further reducing the resistance. The metal contacts 192(a)-192(d) may be positioned on the substrate, on top of the p-DBR layers, and just below the one or more dielectric DBR layers forming the top of the VCSEL. The reduction in the number of p-DBR layers 196 may lead to decreased optical losses due to free carrier absorption, which may be beneficial during high-temperature operations where absorption tends to increase with a greater number of p-DBR layers 196. The fewer layers of p-DBR layers 196 also contribute to lower resistance within the VCSEL 190, enhancing its thermal performance by minimizing heat generation during operation. This example arrangement allows for higher bandwidth capabilities as it reduces potential barriers for charge carriers, facilitating smoother current flow and enabling faster data transmission rates.

FIG. 1D illustrates a VCSEL 190 with only one p-DBR layer 196 positioned above the aperture 194(a) of the VCSEL 190. By eliminating all but one p-DBR layer 196, there is a significant reduction in free carrier absorption that may occurs when light interacts with additional DBR structures. The absence of p-DBR layers may result in enhanced optical efficiency and enable better thermal management since less heat is generated from optical losses. Additionally, without these p-DBR layers 196 obstructing the path of emitted light, the VCSEL 190 may experience an increased mode confinement and improved lasing characteristics within the cavity, leading to more effective single-mode operation.

FIG. 1E illustrates a VCSEL 190 with multiple apertures 194(a) and 194(b). In this example embodiment, an aperture 194(a) positioned above the action region layer 195 and another aperture 194(b) is positioned below the active region layer 195. This dual-aperture design may allow for greater flexibility in managing current and light confinement and enhances overall device performance by enabling different operational modes depending on varying diameters of each aperture 194(a) and 194(b). Furthermore, the presence of multiple apertures 194(a) and 194(b) can facilitate improved coupling efficiency between layers and enhance bandwidth capabilities in the VCSEL 190 by allowing simultaneous access to multiple pathways for light emission or detection.

FIG. 1F illustrates a flip-chipped and bottom-emitting VCSEL 190 with one or more metal connections 192(a), 192(b), and 192(c) connecting to a heatsink 198 or carrier, PCB, or EIC. This example embodiment features a flip-chip design where the substrate 197 acts as an upper layer while integrating thick metal connections 192(a), 192(b), and 192(c) that extend from metal contacts directly to a heatsink 198 below it. Such an arrangement promotes efficient thermal management as it provides an effective pathway for heat extraction away from critical components like junctions where heat accumulation could hinder performance of the VCSEL 190. Additionally, bottom-emitting configurations such as the one illustrated herein allow for direct coupling into fiber optics or other photonic devices without interference from structural elements above them, thus optimizing bandwidth and enhancing operational reliability under various conditions.

FIG. 1G illustrates a VCSEL 190 having metal contacts 192(a) and 192(b) extending into to the cavity of the VCSEL 190 to support mode filtering to promote single mode lasing allowing for longer fiber transmission lengths such as, without limitation, any length up to and including 2 kilometers, e.g., 100 meters, although in other example embodiments, this length may be shorter or longer. In this example embodiment, metal contacts 192(a) and 192(b) are extended into the cavity itself. This placement of the contacts may aid in electrical conduction and serve as a mode filtering mechanism within the laser structure of the VCSEL 190. By acting as filters against unwanted lasing modes due to their proximity to active areas within the cavity, the metal contacts 192(a) and 192(b) help maintain single-mode lasing characteristics essential for high-performance applications.

Alternatively, a separate mode filter could be added, either inside the cavity or outside. FIG. 1H illustrates a VCSEL 190 with mode filter 199 in between the dielectric p-DBR layer 191 and p-DBR layers 196. This mode filter may be added by tuning the epitaxial or dielectric thickness of the one or more layers in the DBR stack at only a single part of the VCSEL area to laterally differentiate the cavity loss. In example embodiments, the epitaxial or dielectric 14 thickness may be scaled as a quarter of the lasing wavelengths or some other suitable proportion. In other example embodiments, the thickness may include any length between 10 to 200 nanometers. This example embodiments employs precise tuning of layer thicknesses within one or more DBR stacks inside the cavity of the VCSEL 190 to create a mode filter 199 that control which wavelengths are allowed to resonate within specific regions of the VCSEL 190 structure. By manipulating these thicknesses selectively across different parts of VCSEL 190, overall efficiency may be enhanced while maintaining desired operational wavelengths.

FIG. 1I illustrates a VCSEL 190 with a mode filter 199 positioned on top of the dielectric DBR layers 191. This mode filter may be added by tuning the epitaxial or dielectric thickness of the one or more layers in the DBR stack at only a single part of the VCSEL area to laterally differentiate the cavity loss. In other example embodiments, integration could include advanced optics or electronic components designed specifically for enhancing interaction with emitted light.

The intracavity implantations and contacts described herein can be extended to coupled cavities (as described elsewhere herein such as, e.g., TCC VCSELs) to push the intrinsic bandwidth of the VCSEL significantly higher in addition to the improvement in parasitic bandwidth. By integrating these implantations and metal contacts into coupled cavities, it may also be possible to achieve a specified bandwidth at lower bias current than without coupled cavities and in this way reduce the power consumption and self-heating of the VCSEL. Furthermore, the intracavity implantation, allowing for sharper and narrower resistive regions, may reduce resistance and lower optical loss when it comes to electrically separating the optically coupled lateral cavities. Example embodiments described herein may also allow the use of only one implant step, or the use of fewer ion energies, as there may no longer be any need for electrical isolation all the way through the top DBR for electrical separation of the lateral cavities.

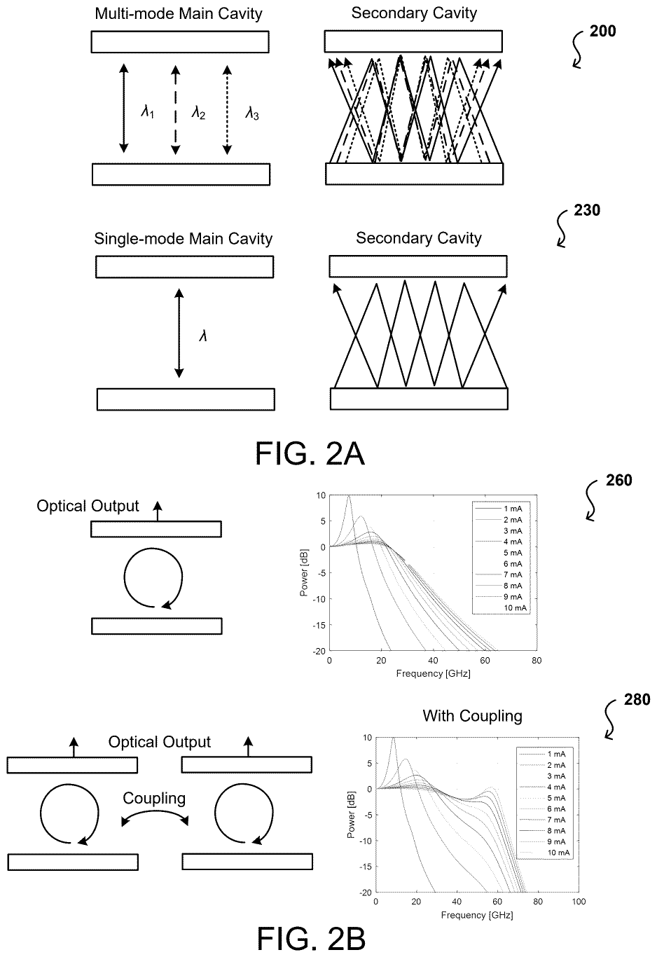

FIG. 2A illustrates an example schematic 200 of wavelength reflection in main and secondary cavities both without (top) and with (bottom) a mode filter in place. In a first arrangement 200 a conventional TCC VCSEL is illustrated that does not include a mode filter, and allows for propagation of light of multiple different wavelengths. As illustrated, this can include reflection in a primary vertical direction (in the figure) in the primary cavity, which supports multiple modes, and reflection back and forth laterally through the secondary cavity. As illustrated, there are multiple lasing wavelengths in a main multi-mode cavity. There are different propagation angles with associated difference in delay times (τ) in the secondary cavity, due at least in part to different propagation lengths and phase (φ). The differences in wavelength may also lead to different coupling coefficients (κ). A second wavelength schematic 230 illustrates a single lasing wavelength in a single-mode cavity, such as may be achieved using at least one mode filter. As illustrated, there is then also a single propagation angle (allowing for a small range of deviation) in the secondary cavity, allowing for predictable and controllable feedback parameters τ, φ, and κ.

As mentioned, TCC VCSEL devices can be modeled as two lasing cavities coherently coupled to each other, or as a primary cavity receiving optical feedback from a secondary cavity after a certain time delay. In such cases, the feedback received from the coupling can help breach the bandwidth limitation set by the resonance frequency of an individual VCSEL by, for example, introducing a shift to higher frequencies or extra resonances in addition to the second order system. As an example, FIG. 2B illustrates a first schematic 260 of a single cavity and simulated modulation response for a conventional VCSEL for different bias currents. By way of comparison, a second schematic 280 is illustrated for coupled cavities, along with a simulated modulation response for a TCC VCSEL for different bias currents. As illustrated, coupling of the cavities with the correct (or appropriate) coupling parameters can help to push the bandwidth possible for a given VCSEL device, which can be important to, for example, ensure sufficient bandwidth for links of an optical communication network.

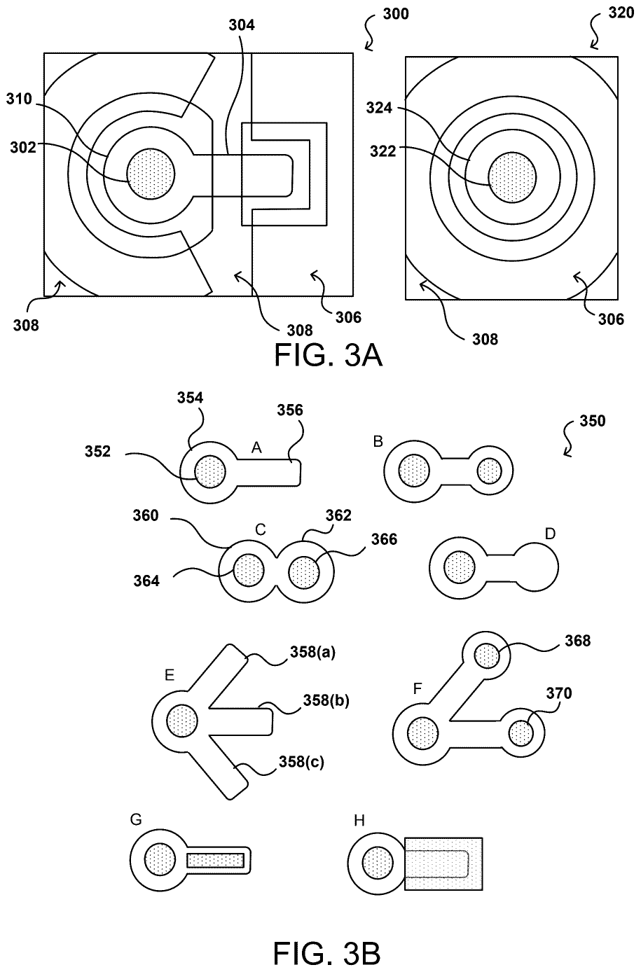

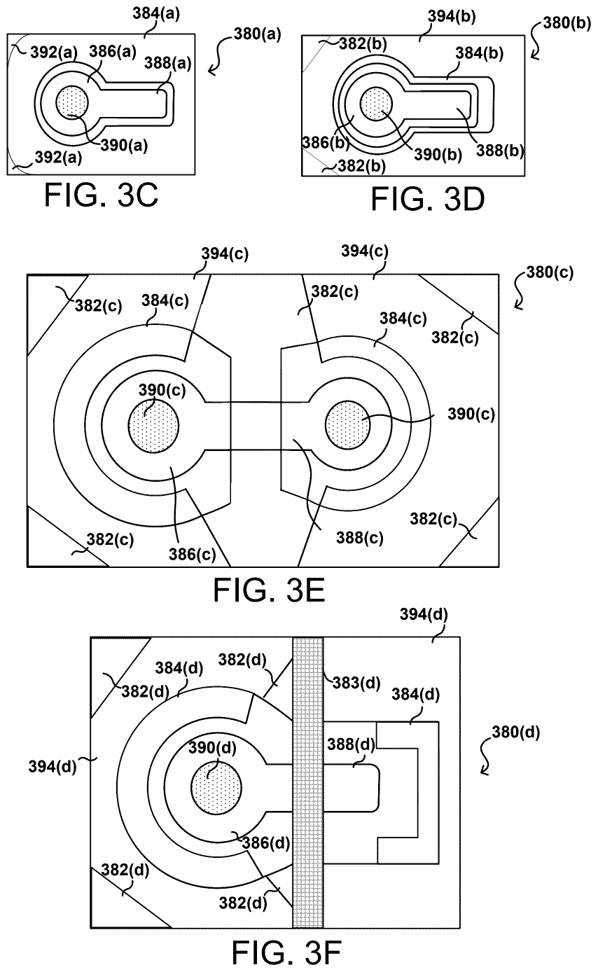

FIG. 3A illustrates a top-view schematic of an example TCC VCSEL 300 having a mode filter 302 in accordance with at least one embodiment. The design of this particular TCC VCSEL has a lateral arm portion acting as a secondary cavity 304. The coupling of the primary cavity 310 to the secondary cavity 304 results in feedback to the primary cavity. Electrical separation of the two cavities, such as through implantation, can help to control the biasing separately. A mode filter 302 positioned with respect to an aperture of the primary cavity 310 can help to ensure that the laser operates in a single mode, or produces light of primarily a single wavelength. A key-shaped aperture is formed through the combination of the primary cavity 310 and the secondary cavity, which controls the lateral (in-plane) extent of the first and secondary cavities. The TCC VCSEL includes a pair of metal contacts 306 for applying an electric signal needed for operation. At least one insulating region 308 can also be used to provide for at least some amount of electric isolation of the cavities. In at least one embodiment, an insulating region 308 can correspond to a region of material that can be used to obtain electrical isolation between devices, components, or regions. For methods of isolation such as ion implantation (i.e., implanting helium or other such ions into a target material or substrate), electrical isolation can result from induced lattice damage, such that the isolation can be controlled through selection of parameters such as ion mass, does, energy, and substrate temperature during implantation, with annealing often being used to further maximize resistivity. Ions of hydrogen, boron, or other such materials can be used as well, with dosing amounts depending upon factors such as the substrate material and amount of electrical isolation to be provided.

An example TCC VCSEL can include at least one lossy secondary cavity coupled in a lateral direction. At least one aperture, such as an oxide aperture, can be positioned in at least the primary cavity, with the mode filter 176 being positioned in line with the aperture 162 (in a parallel plane along a same primary axis, typically with a diameter of the mode filter 178 being in the range of from the full diameter 179 of the optical aperture 162 to half 182 the diameter of the optical aperture 162 as illustrated in FIG. 1B). In example embodiments, the diameter of the mode filter 178 may be less than or equal to the diameter 179 of the aperture 162 of the cavity. In example embodiments, an oxide aperture may refer to a specific structure formed from an oxide material, such as, without limitation, aluminum oxide. This oxide aperture may facilitate optical confinement by creating a refractive index contrast between the active region of the laser and its surroundings, allowing for more efficient lasing action. Referring more generally to the VCSEL, this structure of one or more coupled waveguides introduces lateral optical confinement and a leaky traveling wave in the direction of the TCC (or each TCC for multiple secondary cavities). Unlike a conventional VCSEL design, light generated in the TCC-based laser has an additional lateral component, such as may have an angle close to 90° near the cutoff condition of light propagation. That is, light travels perpendicularly and is slowed in the laterally coupled waveguide. Within a given TCC, the slow light propagates for one or several round trips with group velocity of v_{g}=c/n_{g}, where n_{g}=fn is the group index, n is the average material refractive index, and f is the slow factor of light. The slow light is totally reflected back at the far end of the TCC and is coupled into the VCSEL cavity with a coupling ratio η. The back and forth propagating slow light of the X can suffer a loss or gain, as well as a phase and time delay. Such a configuration can help to enhance the modulation bandwidth (MBW) of a semiconductor laser, such as a VCSEL.

FIG. 3A also illustrates, for comparison, a view of a single cavity VCSEL 320 in which a mode filter 322 could be used with respect to a primary cavity, which provides many of the advantages that can be obtained by using such a mode filter with a TCC VCSEL 300. In addition to a mode filter 322 and aperture 324, an insulating region 308 and metal contact region 306, where the metal contact region 306 partially overlaps the insulating region 308. In addition to the example layouts illustrated in FIG. 3A, there are numerous possible variants 350 of which a few (examples A-H) are depicted in FIG. 3B. In this regard, there may be one or more secondary cavities used, such as where it is desired to have multiple peaks in the response curve to provide a flatter overall response. Individual secondary cavities can be of various sizes and shapes, such as primarily rectangular or circular shapes, or a combinations thereof (examples B, D, F of FIG. 3B), among other such options. Example A includes a primary cavity 354 and a secondary cavity 356 of a device, while Example E illustrates a single primary cavity with three secondary cavities 358(a)-358(c). In Example C, there are two similar cavities 360, 362 where either cavity is capable as serving as a primary cavity or a secondary cavity.

As illustrated, example VCSELs can include one or more mode filters 352, 364, 366, 368, 370, with a first cavity and/or one or more secondary cavities capable of having a mode filter (or no mode filter) in at least one embodiment. A secondary mode filter 366, 368, 370 of a secondary cavity may be for the same mode as for a primary mode filter 352, 364 of the corresponding primary cavity, or may be for a different mode than for the primary cavity and/or at least one other secondary cavity. In at least one embodiment, mode filters can be used that allow for a single mode when propagating. If instead an aperture of a secondary cavity is small enough to only allow for a single mode, the filter may be extended over the entire secondary cavity to minimize losses (example H of FIG. 3B). Some VCSELs may be provided without implantation, only have implantation outside the cavity, or have different implantation depth profiles. Such an approach can provide for different energies, doses, and ion species, between (optimized for electrical isolation) and outside (optimized for low capacitance) the cavities. As illustrated, there may be more than two cavities, with or without filters, and the apertures and filters may have non-circular shapes and/or partly be covered by reflective metal. In example embodiments, the second or additional mode filters may be positioned with respect to the second cavity to promote lasing of the selected wavelength or a secondary wavelength.

FIG. 3C illustrates a view of a VCSEL 380(a) with a primary cavity 386(a) and secondary cavity 388(a) and one or more metal contacts 384(a) as described with further reference to FIGS. 1C-1I. The metal contacts 384(a) may not cover the entire VCSEL 380(a) such that one or more empty spaces 392(a) are present. In example embodiments, the VCSEL 380(a) may also include a mode filter 390(a). In addition to the example layouts illustrated in FIG. 3D, there are numerous possible variants of which a few are depicted in FIGS. 1C-1I and FIGS. 3A-3B. In this regard, there may be one or more secondary cavities 388(a) used, such as where it is desired to have multiple peaks in the response curve to provide a flatter overall response. Individual secondary cavities can be of various sizes and shapes, such as primarily rectangular or circular shapes, or a combinations thereof (examples B, D, and F of FIG. 3B), among other such options. In at least one embodiment, mode filters can be used that allow for a single mode when propagating. If instead an aperture of a secondary cavity 388(a) is small enough to only allow for a single mode, the filter may be extended over the entire secondary cavity 388(a) to minimize losses (example H of FIG. 3B). In other example embodiments, some VCSELs may be provided without implantation, only have implantation outside the cavity, or have different implantation depth profiles.

FIG. 3D illustrates a view of a VCSEL 380(b) with a primary cavity 386(b) and secondary cavity 388(b) and one or more metal contacts 384(b) as described with further reference to FIGS. 1C-1I. The metal contacts 384(b) may cover an area surrounding the primary cavity 386(b) and secondary cavity 388(b). Some areas may not be covered completely by the metal contacts 384(b) thus revealing the one or more underlying implantations 382(b). The area 394(b) may include a layer of implantations beneath a layer of metal contacts 384(b). In example embodiments, the metal contacts 384(b) may be continuous and comprise any shape such as, without limitation, a shape that is similar to the shape or outline of the primary cavity 386(b), secondary cavity 388(b), an aperture, a mode filter, or any element of the VCSEL 380(b). The metal contacts 384(b) may be rectangular, circular, or any suitable shape. In further example embodiments, the metal contacts 384(b) may cover the primary cavity 386(b), secondary cavity 388(b), or any sections of the VCSEL 380(b). In example embodiments, the VCSEL 380(b) may also include a mode filter 390(b). In addition to the example layouts illustrated in FIG. 3D, there are numerous possible variants of which a few are depicted in FIGS. 1C-1I and FIGS. 3A-3B. In this regard, there may be one or more secondary cavities 388(b) used, such as where it is desired to have multiple peaks in the response curve to provide a flatter overall response. Individual secondary cavities can be of various sizes and shapes, such as primarily rectangular or circular shapes, or a combinations thereof (examples B, D, and F of FIG. 3B), among other such options. In at least one embodiment, mode filters can be used that allow for a single mode when propagating. If instead an aperture of a secondary cavity 388(b) is small enough to only allow for a single mode, the filter may be extended over the entire secondary cavity 388(b) to minimize losses (example H of FIG. 3B). Furthermore, the VCSEL 380(b) may include one or more implantations 382(b) outside of the primary cavity 386(b) and secondary cavity 388(b).

FIG. 3E illustrates a view of a VCSEL 380(c) with a primary cavity 386(c) and secondary cavity 388(c) and one or more implantations 382(c) and metal contacts 384(c) as described with further reference to FIGS. 1C-1I. The metal contacts 384(c) may not cover an area surrounding the primary cavity 386(c) and secondary cavity 388(c). Some areas may not be covered completely by the metal contacts 384(c) thus revealing the one or more underlying implantations 382(c). The area 394(c) may include a layer of implantations beneath a layer of metal contacts 384(c). In example embodiments, the VCSEL 380(c) may also include one or more mode filters 390(c). In addition to the example layouts illustrated in FIG. 3E, there are numerous possible variants of which a few are depicted in FIGS. 1C-1I and FIGS. 3A-3B. In this regard, there may be one or more secondary cavities 388(c) used, such as where it is desired to have multiple peaks in the response curve to provide a flatter overall response. Individual secondary cavities can be of various sizes and shapes, such as primarily rectangular or circular shapes, or a combinations thereof (examples B, D, and F of FIG. 3B), among other such options. In at least one embodiment, mode filters can be used that allow for a single mode when propagating. If instead an aperture of a secondary cavity 388(c) is small enough to only allow for a single mode, the filter may be extended over the entire secondary cavity 388(c) to minimize losses (example H of FIG. 3B). Furthermore, the VCSEL 380(c) may include one or more implantations 382(c) outside of the primary cavity 386(c) and secondary cavity 388(c).

FIG. 3F illustrates a view of a VCSEL 380(d) with a primary cavity 386(d) and secondary cavity 388(d) and one or more implantations 382(d) and metal contacts 384(d) as described with further reference to FIGS. 1C-1I and 3C-3F. Some areas may not be covered completely by the metal contacts 384(d) thus revealing the one or more underlying implantations 382(d). The area 394(d) may include a layer of implantations beneath a layer of metal contacts 384(d). In some embodiments, implantations 383(d) may at a different layer of depth relative to the metal contacts 394(d). In example embodiments, the VCSEL 380(d) may also include a mode filter 390(d). In addition to the example layouts illustrated in FIG. 3F, there are numerous possible variants of which a few are depicted in FIGS. 1C-1I and FIG. 3B. In this regard, there may be one or more secondary cavities 388(d) used, such as where it is desired to have multiple peaks in the response curve to provide a flatter overall response. Individual secondary cavities can be of various sizes and shapes, such as primarily rectangular or circular shapes, or a combinations thereof (examples B, D, and F of FIG. 3B), among other such options. Further, other example embodiments may include a secondary mode filter of the secondary cavity 388(d) may be for the same mode as for the mode filter 390(d) of the corresponding primary cavity 386(d). In at least one embodiment, mode filters can be used that allow for a single mode when propagating. If instead an aperture of a secondary cavity 388(d) is small enough to only allow for a single mode, the filter may be extended over the entire secondary cavity 388(d) to minimize losses (example H of FIG. 3B). In other example embodiments, some VCSELs may be provided without implantation, only have implantation outside the cavity, or have different implantation depth profiles. Furthermore, the darker shaded and lighter shaded areas 382(d) indicate different implantation profiles, e.g., the darker shaded implantations may be of a shallower depth than the lighter shaded implantations or vice versa.

There may be multiple types of mode filters used as well, which may have different shapes and sizes as may be appropriate for the respective cavity shape and size, as well as the size and shape of the respective aperture and mode to be selected, among other such options. As mentioned, a mode filter can be inverted surface relief etched into a top layer of a semiconductor, as illustrated in FIG. 2A. In other embodiments, a mode filter could be fabricated using a positive surface relief, a relief etched into a dielectric material, a relief inside the DBR mirror buried by overgrowth or dielectric DBR deposition, or by a metal mirror, among other such options. The aperture of a cavity may also be of various sizes and shapes as appropriate, and may be created using various approaches, such as through oxidation by appropriately designing the mesa shape, by a buried tunnel junction, or a separate implantation step, among other such options.

As mentioned, a modulation response of a TCC VCSEL can be exceptionally sensitive to the nature of the feedback, such as the feedback strength, phase, and time constant. These parameters depend on the geometry of the cavities but also strongly on the lasing wavelength and operation conditions of a TCC VCSEL. The wavelength can therefore (at least partially) determine the angle of propagation in the external cavity, and thereby the phase and time delay. The wavelength may also affect the mode profile and in this way the coupling coefficient and feedback strength. If the lasers are multimode, with multiple transverse modes lasing at different wavelengths, the feedback and, in turn, the bandwidth may become unstable and unpredictable where small variations in, for example, ambient temperature or biasing could drastically alter the bandwidth. If there are many wavelengths, the effect from the different feedback components may also counteract and prevent the wanted bandwidth increase. It is possible to use lasers with very small apertures to achieve single-mode lasing, but these are harder to fabricate, have high electrical resistance, and low output power. Approaches in accordance with various embodiments can improve the predictability and controllability of TCC VCSELs through the use of one or multiple mode filters as discussed, which can make it possible to achieve single-mode, stable, low electrical resistance and relatively high power TCC VCSELs with bandwidth much higher than those achievable using conventional VCSEL structures. Such approaches can allow for pushing VCSEL-based lane rates from 100 Gbit/s to 200 Gbit/s and beyond while maintaining or reducing energy consumption per bit. In addition, stable single-mode TCC VCSELs can be used as neuron-like building blocks in compact neuromorphic photonics computing systems, among other such operations or applications. For example, TCC VCSELs can display diverse spiking behaviors influenced by modulation settings and coupling intensity, positioning them as suitable components for integrated photonic neural networks. Additionally, TCC VCSELs can produce bistable outputs with a significant hysteresis loop. An electrical or optical signal can trigger these VCSELs to alternate between stable states, creating sharp optical pulses (spikes) that are highly modifiable and adjustable. Also as mentioned, electric isolation can also be used to further improve controllability of feedback, as may be implemented using implantation or another such process leading to control of flow of electrical current area(s).

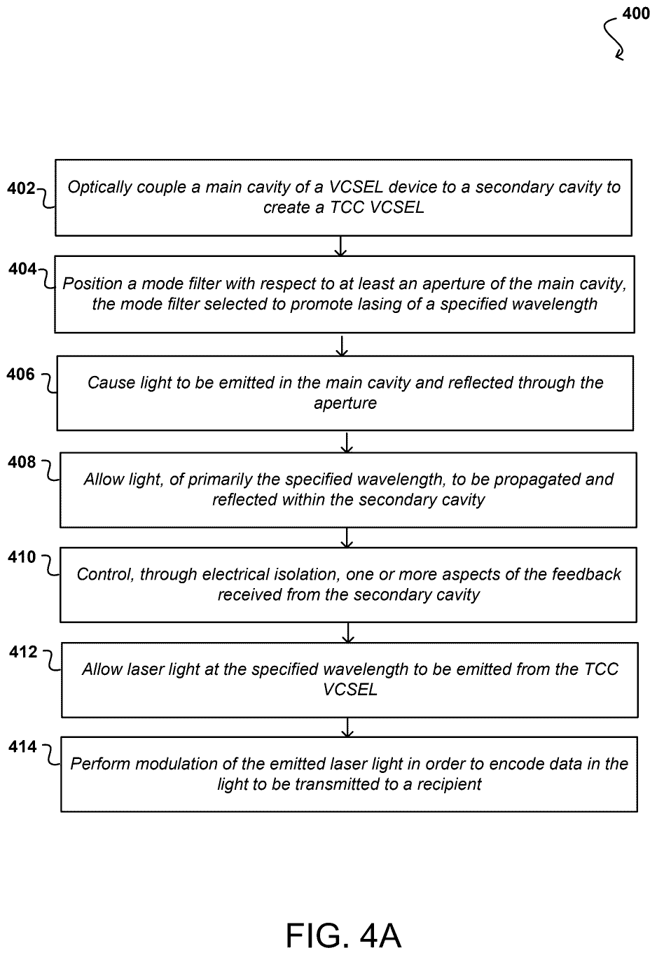

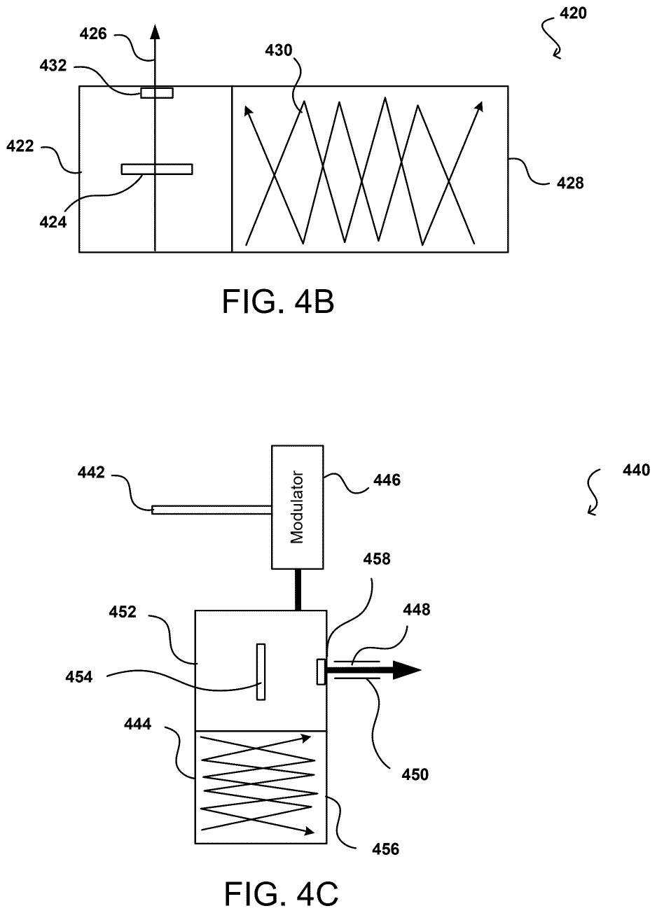

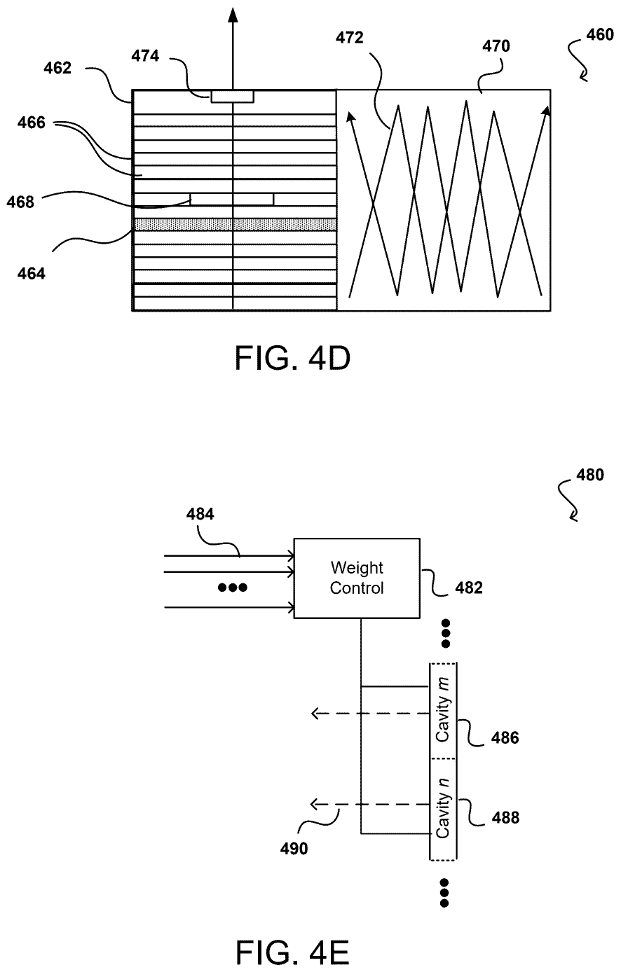

FIG. 4A illustrates an example process 400 that can be performed to generate light of a single mode from a laser device, in accordance with at least one embodiment. It should be understood that for this and other processes discussed herein that there may be additional, fewer, or alternative steps performed in similar or alternative orders, or at least partially in parallel, within the scope of the various embodiments. Further, although discussed with respect to TCC VCSELs and mode filters, it should be understood that advantages of such a process can be obtained for other types of light-emitting devices or mode selection mechanisms as well within the scope of various embodiments. In this example process, a primary cavity of a laser device, such as a VCSEL, is optically coupled 402 to at least one secondary cavity to create a TCC VCSEL. As mentioned, the secondary cavities can be of various sizes, shapes, numbers, and other such aspects. A mode filter can be positioned 404 (or formed) with respect to at least an aperture of the primary cavity, where the mode filter is selected (or formed) to promote lasing of a specified wavelength in the VCSEL. As mentioned, a mode filter (for the same wavelength or a different wavelength) can be positioned in at least one secondary cavity as well in some embodiments. Light can be caused 406 to be generated in the primary cavity and reflected by layers of the primary cavity through the respective aperture. Light of primarily the specified wavelength can also be allowed 408 to be propagated and reflected within the secondary cavity, resulting in optical feedback from the secondary cavity. Electrical isolation, or another such mechanism, can be used to control 410 one or more aspects of the feedback received from the secondary cavity, where those aspects can include strength, phase and/or time constant, among other such options. The spectral output and modulation response of the TCC VCSELs described herein can be managed by modifying the size and design of the current apertures and modal filters. In example embodiments, spectral output may refer to the distribution of intensity of light or other electromagnetic radiation as a function of wavelength or frequency. The laser light at the specified wavelength can then be allowed 412 to be emitted from the TCC VCSEL in a determined direction. Modulation of this emitted laser light can be performed 414 in order to encode data in the light to be transmitted to a recipient, such as over an optical fiber of a communication network. There may be various other uses for such light as well, as discussed and suggested elsewhere herein.

FIG. 4B illustrates an example laser device 420 according to at least one embodiment. This example device comprises a vertical cavity surface-emitting laser (VCSEL) including a first cavity 422 and an optical aperture 424 to generate laser light to be emitted in a first direction 426. This example device 420 also includes a second cavity 428 transversely coupled to the first cavity 422 to allow at least a portion 430 of the laser light, generated in the first cavity 422, to be reflected within both the first cavity 422 and the second cavity 428. Although the secondary cavity is illustrated to be of the same height but longer than the primary cavity, it should be understood that such dimensions can vary in alternative embodiments, particularly where there may be multiple secondary cavities. The example device also includes a mode filter 432 positioned (or formed) with respect to the first cavity 422 to promote lasing of a selected wavelength of the laser light 426 to be emitted. As illustrated, a mode filter 432 in such a device will typically be placed proximate an exit of the laser light from the first cavity 422. In at least one embodiment, the filter will allow for passage of the laser light 426 to be emitted, with the mode filter having a diameter (such as the diameter 178 illustrated in FIG. 1B). As illustrated, this diameter will typically be orthogonal to the direction of the output laser light 180. In some embodiments, a mode filter 432 may be positioned along the direction of the laser light 180 to be output, but may be formed in a different layer. An advantage of placing the mode filter 176 at an edge of cavity is that the mode filter 176 can be etched into the top layer, where if a mode filter is in an intermediate layer then an additional step or piece may be required to ensure that the mode filter properties are adequate after formation of the surrounding material.

FIG. 4C illustrates an example optical communication system according to at least one embodiment. This example system comprises an electrical input 442 to receive an electrical signal, and a laser device 444 to emit laser light to be propagated via an optical transmission mechanism 450, such as an optical fiber. The example system also includes a modulator 446 to apply modulation electrically using contacts (e.g., contact 168 and 170(a)-(b) of FIG. 1B), which will be converted to modulated output light, such as is depicted schematically in FIG. 1A. The modulation can be used in order to encode, in the modulated output light, data from the received electrical signal. The laser device 444 in this example system includes a vertical cavity surface-emitting laser including a first cavity 452 and an optical aperture 454 to generate laser light to be emitted in a first direction 448. The laser device further includes a second cavity 456 transversely coupled to the first cavity 452 to allow at least a portion of the laser light, generated in the first cavity 452, to be reflected within both the first cavity 452 and the second cavity 456. The example laser device 444 also includes a mode filter 458 positioned with respect to the first cavity 452 to promote lasing of a selected wavelength of the light to be emitted.

FIG. 4D illustrates a single mode, transverse-coupled cavity, vertical cavity surface-emitting laser (TCC VCSEL), according to at least one embodiment. This example VCSEL comprises a primary cavity 462 including an active layer 464, a plurality of reflective layers 466, and a primary optical aperture 468 to cause lasing of light of one or more wavelengths in a first direction. This example VCSEL further comprises a secondary cavity 470 transversely coupled to the primary cavity 462 to allow at least a portion 472 of the light, generated in the first cavity 462, to be reflected within both the primary cavity 462 and the secondary cavity 470 and to provide feedback to the primary cavity 462. This example VCSEL also comprises a mode filter 474 positioned with respect to the primary cavity 462 to promote lasing of a selected wavelength of the light to be emitted.

FIG. 4E illustrates an example of a VCSEL that is able to function as an excitable laser in a photonics neural network according to at least one embodiment. In this example, one or more inputs 484 (either electrical or optical) can be received to a weight control module 482. The weight control module can communicate with two or more cavities 486, 488 of a TCC VCSEL to emit optical output 490 from one or more of those cavities 486, 488, as discussed above with respect to FIG. 3B. The optical output(s) can each be at a selected wavelength (either at the same wavelength or different wavelength) and can be emitted concurrently or at different times, as may be determined by the weight control module in response to processing the input 484. Such selectable output can be used, based on features and benefits discussed in more detail elsewhere herein, to provide the ultra-high throughput and low energy consumption typically required for photonics neural networks.

### Data Center

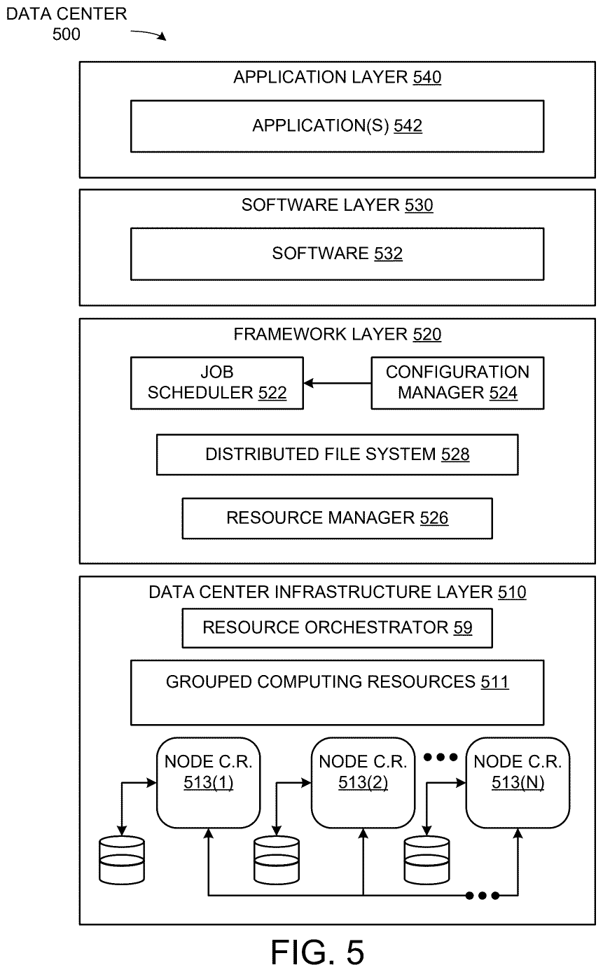

FIG. 5 illustrates an example data center 500, in which at least one embodiment may be used. For example, TCC VCSEL devices may be used to transmit data via optical communication within, into, or from such a data center as part of a communication network and/or infrastructure. In at least one embodiment, data center 500 includes a data center infrastructure layer 510, a framework layer 520, a software layer 530 and an application layer 540.

In at least one embodiment, as shown in FIG. 5, data center infrastructure layer 510 may include a resource orchestrator 512, grouped computing resources 514, and node computing resources (“node C.R.s”) 516(1)-516(N), where “N” represents a positive integer (which may be a different integer “N” than used in other figures). In at least one embodiment, node C.R.s 516(1)-516(N) may include, but are not limited to, any number of central processing units (“CPUs”) or other processors (including accelerators, field programmable gate arrays (FPGAs), graphics processors, etc.), memory storage devices 518(1)-518(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 516(1)-816(N) may be a server having one or more of above-mentioned computing resources. In other embodiments, the processors or processing units may include a central processing unit (CPU) or graphics processing unit (GPU)), data processing units (DPUs), quantum processing units (QPUs), a plurality of parallel processing units (PPUs), and application-specific integrated circuits (ASICs) memory module, or power supply. QPUs configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

In at least one embodiment, grouped computing resources 514 may include separate groupings of node C.R.s housed within one or more racks (not shown), or many racks housed in data centers at various geographical locations (also not shown). In at least one embodiment, separate groupings of node C.R.s within grouped computing resources 514 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 512 may configure or otherwise control one or more node C.R.s 516(1)-516(N) and/or grouped computing resources 514. In at least one embodiment, resource orchestrator 512 may include a software design infrastructure (“SDI”) management entity for data center 500. In at least one embodiment, resource orchestrator 512 may include hardware, software or some combination thereof.

In at least one embodiment, as shown in FIG. 5, framework layer 520 includes a job scheduler 522, a configuration manager 524, a resource manager 526 and a distributed file system 528. In at least one embodiment, framework layer 520 may include a framework to support software 532 of software layer 530 and/or one or more application(s) 542 of application layer 540. In at least one embodiment, software 532 or application(s) 542 may respectively include web-based service software or applications, such as those provided by Amazon Web Services, Google Cloud and Microsoft Azure. In at least one embodiment, framework layer 520 may be, but is not limited to, a type of free and open-source software web application framework such as Apache Spark™ (hereinafter “Spark”) that may utilize distributed file system 528 for large-scale data processing (e.g., “big data”). In at least one embodiment, job scheduler 522 may include a Spark driver to facilitate scheduling of workloads supported by various layers of data center 500. In at least one embodiment, configuration manager 524 may be capable of configuring different layers such as software layer 530 and framework layer 520 including Spark and distributed file system 528 for supporting large-scale data processing. In at least one embodiment, resource manager 526 may be capable of managing clustered or grouped computing resources mapped to or allocated for support of distributed file system 528 and job scheduler 522. In at least one embodiment, clustered or grouped computing resources may include grouped computing resources 514 at data center infrastructure layer 510. In at least one embodiment, resource manager 526 may coordinate with resource orchestrator 512 to manage these mapped or allocated computing resources.

In at least one embodiment, software 532 included in software layer 530 may include software used by at least portions of node C.R.s 516(1)-516(N), grouped computing resources 514, and/or distributed file system 528 of framework layer 520. In at least one embodiment, one or more types of software may include, but are not limited to, Internet web page search software, e-mail virus scan software, database software, and streaming video content software.

In at least one embodiment, application(s) 542 included in application layer 540 may include one or more types of applications used by at least portions of node C.R.s 516(1)-516(N), grouped computing resources 514, and/or distributed file system 528 of framework layer 520. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 524, resource manager 526, and resource orchestrator 512 may implement any number and type of self-modifying actions based on any amount and type of data acquired in any technically feasible fashion. In at least one embodiment, self-modifying actions may relieve a data center operator of data center 500 from making possibly bad configuration decisions and possibly avoiding underutilized and/or poor performing portions of a data center.

In at least one embodiment, data center 500 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 500. In at least one embodiment, trained machine learning models corresponding to one or more neural networks may be used to infer or predict information using resources described above with respect to data center 500 by using weight parameters calculated through one or more training techniques described herein.

In at least one embodiment, data center may use CPUs, application-specific integrated circuits (ASICs), GPUs, FPGAs, DPUs, QPUs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Embodiments presented herein can provide for the emission of a single wavelength of light from a laser device such as a TCC VCSEL through use of at least one mode filter.

### Transceiver Module

A computer system can be used to generate data to be converted into optical signals for transmission, such as by using one or more TCC VCSELs. Such a computer system may also control operation of a VCSEL-based transmitter or transceiver, as discussed herein. Embodiments presented herein can provide for the emission of a single wavelength of light from a laser device such as a TCC VCSEL through use of at least one mode filter.

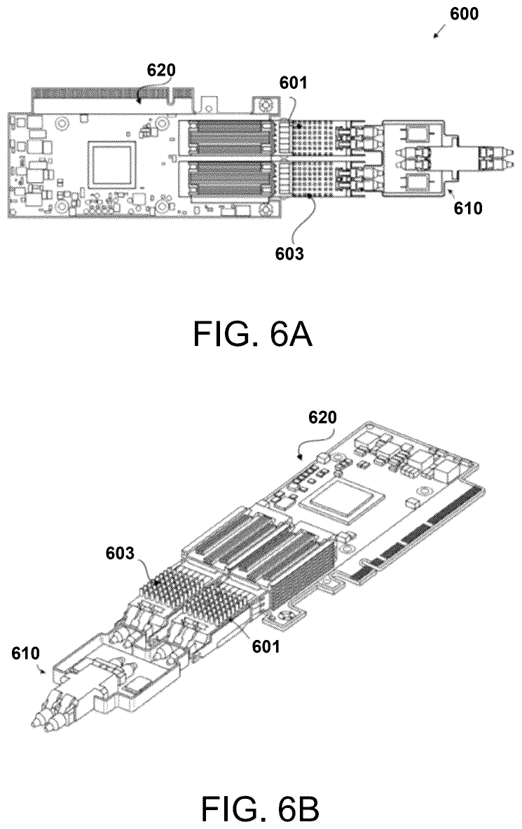

FIGS. 6A and 6B illustrate a top view and a perspective view, respectively, of a transceiver module operatively coupled to a network adapter, in the present example a Network Interface Controller (NIC) 600, in accordance with an embodiment of the disclosure. As shown in FIGS. 6A and 6B, the transceiver module may include a first optical module 601, a second optical module 603, an adapter 610, and a dual-port NIC 620 of a server. Both the first optical module 601 and the second optical module 603 may be dual-fiber transceivers that are configured for duplex communication that allows the source (e.g., server) to communicate with the target (e.g., leaf switch) in both directions. The adapter 610 may be a ganged physical component configured to link the first optical module 601 and the second optical module 603 for the purpose of transmitting and receiving data to and from the leaf switch.

In some embodiments, the adapter 610 may be configured to operate in two configurations, such as a first configuration and a second configuration. In one aspect, the first configuration may be a default configuration of operation, where the first optical module 601 may be operationally active. The second configuration may be a contingent configuration that is implemented when the first optical module 601 operationally fails. When such a failure is detected, the second optical module 603, which is otherwise operationally inactive or idle, may be engaged become operationally active and handle all network traffic that was initially handled by the first optical module 601. In some embodiments, the transceiver module 600 may be configured to operate in a leaf-spine architecture. A leaf-spine architecture is a data center network topology that may include two switching layers—a spine layer and a leaf layer. The leaf layer may include access switches (leaf switches) that aggregate traffic from servers and connect directly into the spine or network core. Spine switches interconnect all leaf switches in a full-mesh topology between access switches in the leaf layer and the servers from which the access switches aggregate traffic. As such, in one embodiment, to ensure reliable operation of downlinks, the transceiver module 600 may be configured to operate between the server and the leaf layer. In particular, as shown in FIGS. 6A and 6B, the adapter 610 may be operatively coupled to the first optical module 601 and the second optical module 603, while the first optical module 601 and the second optical module 603 may be operatively coupled to a dual-port NIC 620 of a server. In some example embodiments, NIC 600 may comprise one or more processing circuits, as detailed above; the processing circuits may comprise FW, that is loaded according to the techniques described above.

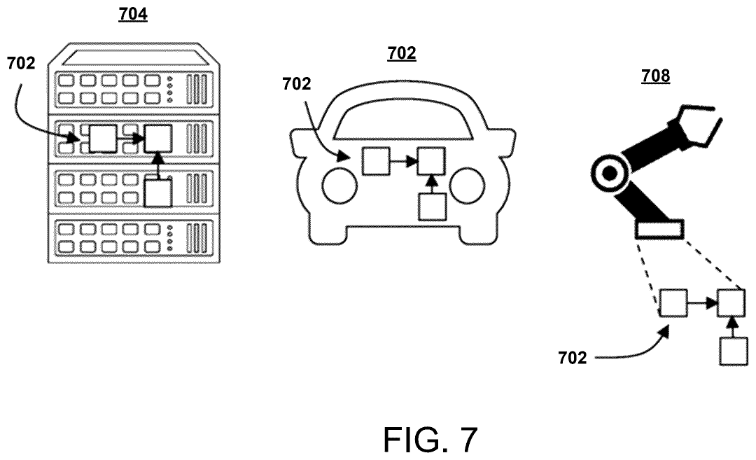

FIG. 7 depicts exemplary scenarios for use of an optical transceiver 702 in accordance with some embodiments. An optical transceiver 702 may be utilized in a computing system 704 (e.g., in a server farm, or within a server computer system), a vehicle 706 (e.g., a car, truck, train, or airplane), and a robot 708 (or among robots in a factory), to name just a few examples. The optical transceiver 702 may be particularly useful for high-speed communication in environments subject to high levels of electromagnetic interference (EMI).

Embodiments presented herein can provide for the emission of a single wavelength of light from a laser device such as a TCC VCSEL through use of at least one mode filter.

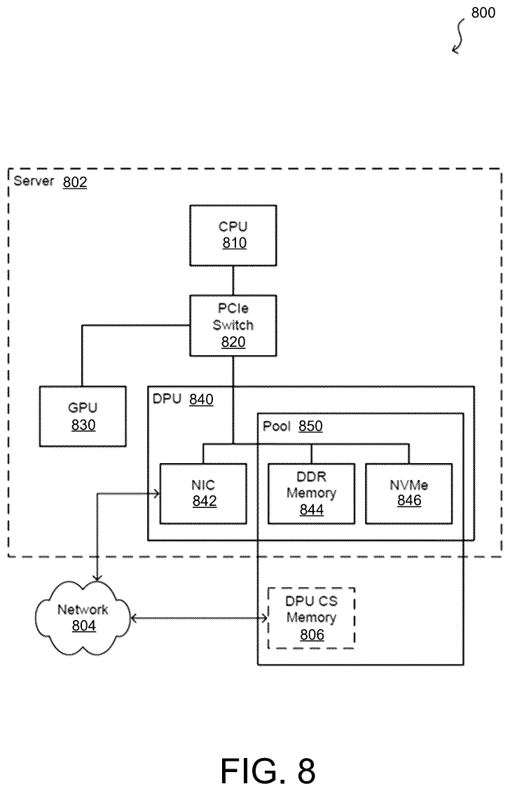

FIG. 8 illustrates an example computing environment 800 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 800 may include a server 802 which may be used to perform HPC workloads, such as AI training or machine learning model training. In an embodiment, the server 802 may be an application instance or a compute node. The server 802 may include a CPU 810 associated with a switch 820, such as a peripheral component interconnect express (PCIe) switch, which may control at least some data transmission over communication paths interconnecting various components. In an embodiment, the CPU 810 may include a root complex processor.

The PCIe switch 820 may also be associated with a GPU 830 and a DPU 840, and may transmit data between at least some of the CPU 810, the GPU 830, the DPU 840, and other components. In an embodiment, the PCIe switch 820 may be associated with more than one GPU or more than one DPU. In another embodiment, the PCIe switch 820 may be located within the DPU 840. The PCIe switch 820 may manage the transfer of at least some data between the CPU 810, the GPU 830, and the DPU 840. In another embodiment, the number of GPUs associated with the PCIe switch 820 may be equal to the number of DPUs associated with the PCIe switch 820. In at least one embodiment, the server 802 may include, without limitation, any number of the CPUs 810, the PCIe switches 820, the GPUs 830, and/or the DPUs 840, in any combination. For example, in at least one embodiment, server 802 could include eight, sixteen, thirty-two, and/or more GPUs 830. In at least one embodiment, communication paths interconnecting various components, including but not limited to the CPU 810, the PCIe switch 820, the GPU 830, and the DPU 840, in FIG. 8 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 840 may include a network interface card (NIC) 842, a DDR memory 844, and a non-volatile memory express (NVMe) device 846. The NIC 842 may be able to interface with a network 804, which may also interface with additional NVMe devices available to the DPU 840, such as over fabric. In an embodiment, the DPU 840 may not include the NVMe device 846. In another embodiment, the NVMe device 846 may be located on the server 802 and not on the DPU 840. In yet another embodiment, the computing environment 800 may include more than one of the NVMe device 846, such as a first NVMe device in the DPU 840 and a second first NVMe device on the server 802 an associated directly with the PCIe switch 820. In an embodiment, the DPU 840 may not include the DDR memory 844 and may include a computational storage services (CSS) in place of, or in addition to, the DDR memory 844. For example, computing environment 800 may include DPU computational storage (CS) memory 806 available to the DPU 840 as part of the CSS. The network 804 may be able to interface with the DPU CS memory 806 through the NIC 842, according to any suitable interface protocol, such as remote direct memory access (RDMA) over Ethernet, InfiniBand, Fiber Channel, etc.

The total memory of the computing environment 800 available for data storage may be expanded through the use of the DPU 840 on nodes of the system. The DPU 840 may have access to a pool 850 of memory already available to the server 802, such as double data rate (DDR) memory, on-board NVMe devices, NVMe devices over fabric, and CS. The pool 850 of memory may include at least one of the DDR memory 844, NVMe 846, and the DPU CS memory 806. The DPU 840 may also be able to access the available memory of other DPUs as part of the pool 850, and other DPUs may be able to access the available memory of DPU 840, such as the pool 850. This available memory can be accessed and utilized for data storage, without the addition of compute resources, such as compute nodes, which would be required using other solutions. The available pool 850 accessible to the DPU 840 may be provisioned for the server 802 to expand the total memory available for data storage, such as to reduce the data storage load on the CPU 810 or the GPU 830, which can instead increase the utilization of their memory for processing. For example, during training of an AI, the model states, residual states, activation functions, and checkpoints can be stored, or offloaded, on the pool 850 accessible to the DPU 840.

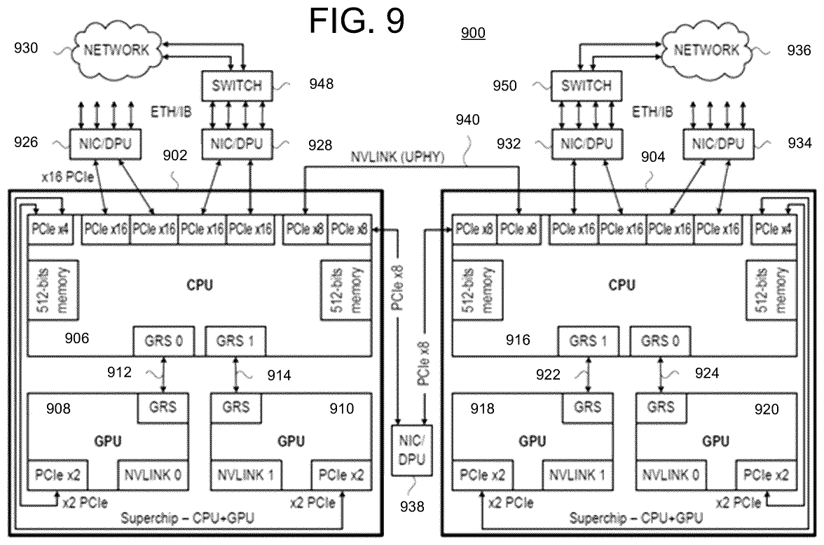

FIG. 9 is a block diagram that schematically illustrates a computing system 900, e.g., a data center or a High-Performance Computing (HPC) cluster, in accordance with an embodiment that is described herein. System 900 comprises a plurality of subsystems, e.g., multiple processing devices coupled to each other, multiple network devices, and multiple networks, according to at least one embodiment. Computing system 900 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 900 and to one or more external networks 930, 936. In the present example, system 900 comprises a packet switch 948 that connects NIC/DPU 928 to network 930, and a packet switch 950 that connects NIC/DPU 932 to network 936.

The coupling of processing devices through NVLink allows for seamless data exchange and parallel processing, enhancing overall computational performance. The processing devices are connected to multiple networks through one or more network interface cards (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 900 can include one or more CPUs and one or more GPUs.

FIG. 9 also demonstrates an example architecture of a multi-GPU architecture. As illustrated in the figure, computing system 900 includes a processing device 902 with a multi-GPU architecture. In particular, processing device 902 may be a system-on-chip and includes multiple subsystems such as a CPU 906, a GPU 908, and a GPU 910. CPU 906 can be coupled to GPU 908 via a die-to-die (D2D) or chip-to-chip (C2C) interconnect 912, such as a Ground-Referenced Signaling interconnect (GRS interconnect). CPU 906 can be coupled to GPU 910 via a D2D or C2C interconnect 914. CPU 906 can also couple to GPU 908 and GPU 910 via PCIe interconnects.

CPU 906 can be coupled to one or more NICs or DPUs, which are coupled to one or more networks. For example, as illustrated in FIG. 9, CPU 906 is coupled to a first NIC/DPU 926, which is coupled to a network 930. CPU 906 is also coupled to a second NIC/DPU 928, which is coupled to network 930 via switch 948. NIC/DPU 926 and NIC/DPU 928 can be coupled to network 930 over Ethernet (ETH), NVLINK or InfiniBand (IB) connections, for example.

Computing system 900 also includes a processing device 904 with a multi-GPU architecture. In particular, processing device 904 includes multiple subsystems including a CPU 916, a GPU 918, and a GPU 920. CPU 916 can be coupled to GPU 918 via an D2D or C2C interconnect 922. CPU 916 can be coupled to GPU 920 via a D2D or C2C interconnect 924. CPU 916 can also couple to GPU 918 and GPU 920 via PCIe interconnects. CPU 916 can be coupled to one or more NICs or DPUs, which are coupled to one or more networks. For example, as illustrated in FIG. 9, CPU 916 is coupled to a first NIC/DPU 932, which is coupled to a network 936. CPU 916 is also coupled to a second NIC/DPU 934, which is coupled to network 936 via switch 950. NIC/DPU 932 and NIC/DPU 934 can be coupled to network 936 over Ethernet (ETH), NVLINK or InfiniBand (IB) connections.

In at least one embodiment, processing device 902 and processing device 904 can communication with each other via a NIC/DPU 938, such as over PCIe interconnects. Processing device 902 and processing device 904 can also communicate with each other over a high-bandwidth communication interconnects 940, such as an NVLink interconnect or other high-speed interconnects. The packet switches in FIG. 9 may comprise, for example, Nvidia Quantum-2 switches. The NICs/DPUs in the figure may comprise, for example, Nvidia Bluefield DPUs.

In various embodiments, any of the network devices of system 900, e.g., any of NICs/DPUs 926, 928, 932, 934 and 938, and/or any of switches 948 and 950, may use ILI packets in accordance with the techniques described herein.

Various embodiments can be described by the following clauses:
1. A laser device, comprising:
a vertical cavity surface-emitting laser (VCSEL) including a first cavity and an optical aperture to generate laser light to be emitted in a first direction;
a second cavity transversely coupled to the first cavity to allow at least a portion of the laser light, generated in the first cavity, to be reflected within both the first cavity and the second cavity; and
a mode filter positioned with respect to the first cavity to promote lasing of a selected wavelength of the laser light to be emitted.
2. The laser device of clause 1, wherein the mode filter has a lateral dimension that is less than, or equal to, a diameter of the optical aperture of the first cavity.
3. The laser device of clause 1, further comprising:
   a second mode filter positioned with respect to the second cavity to promote lasing of the selected wavelength or a secondary wavelength.
4. The laser device of clause 1, wherein the emitted laser light is capable of achieving a higher modulation bandwidth in an optical communication system than if generated using only the first cavity or without the mode filter.
5. The laser device of clause 1, further comprising:
   at least one insulating region to electrically isolate the first cavity from the second cavity.
6. The laser device of clause 5, wherein the at least one insulating region is selected to control one or more feedback parameters from the secondary cavity, the one or more feedback parameters including at least a strength, a phase, or a time constant of feedback.
7. The laser device of clause 1, wherein at least one of the first cavity or the second cavity has a circular shape, an oval shape, a rectangular shape, or a square shape.
8. The laser device of clause 1, wherein the first cavity and the second cavity are formed together on a single wafer or substrate.
9. The laser device of clause 1, wherein the laser device is a transverse-coupled cavity, vertical cavity surface-emitting laser (TCC VCSEL) device.
10. An optical communication system, comprising:
an electrical input to receive an electrical signal;
a laser device to emit laser light to be propagated via an optical transmission mechanism; and
a modulator to modulate the laser light emitted from the laser device in order to encode data from the received electrical signal,
wherein the laser device includes:
a vertical cavity surface-emitting laser including a first cavity and an optical aperture to generate laser light to be emitted in a first direction;
a second cavity transversely coupled to the first cavity to allow at least a portion of the laser light, generated in the first cavity, to be reflected within both the first cavity and the second cavity; and
a mode filter positioned with respect to the first cavity to promote lasing of a selected wavelength of the light to be emitted.
11. The optical communication system of clause 10, wherein the mode filter has a lateral dimension that is less than, or equal to, a diameter of the optical aperture of the first cavity.
12. The optical communication system of clause 10, wherein the laser device further includes a second mode filter positioned with respect to the second cavity to promote lasing of the selected wavelength or a secondary wavelength.
13. The optical communication system of clause 10, wherein the emitted laser light is capable of achieving a higher modulation bandwidth in an optical communication system than if generated using only the first cavity or without the mode filter.
14. The optical communication system of clause 10, wherein the laser device further includes at least one insulating region to electrically isolate the first cavity from the second cavity.
15. The optical communication system of clause 14, wherein at least one insulating region is selected to control one or more feedback parameters from the secondary cavity, the one or more feedback parameters including at least a strength, phase, or time constant of feedback.
16. The optical communication system of clause 10, wherein the optical communication system is used with at least one of:
a system for performing simulation operations;
a system for performing simulation operations to test or validate autonomous machine applications;
a system for performing digital twin operations;
a system for performing light transport simulation;
a system for rendering graphical output;
a system for performing deep learning operations;
a system for performing generative AI operations using a large language model (LLM);
a system implemented using an edge device;
a system for generating or presenting virtual reality (VR) content;
a system for generating or presenting augmented reality (AR) content;
a system for generating or presenting mixed reality (MR) content;
a system incorporating one or more Virtual Machines (VMs);
a system implemented at least partially in a data center;
a system for performing hardware testing using simulation;
a system for performing generative operations using a language model (LM);
a system for synthetic data generation;
a collaborative content creation platform for 3D assets; or
a system implemented at least partially using cloud computing resources.
17. A single mode, transverse-coupled cavity, vertical cavity surface-emitting laser (TCC VCSEL), comprising:
a primary cavity including an active layer, a plurality of reflective layers, and a primary optical aperture to cause lasing of light of one or more wavelengths in a first direction;
a secondary cavity transversely coupled to the primary cavity to allow at least a portion of the light, generated in the first cavity, to be reflected within both the primary cavity and the secondary cavity and to provide feedback to the primary cavity; and
a mode filter positioned with respect to the primary cavity to promote lasing of a selected wavelength of the light to be emitted.
18. The single mode TCC VCSEL of clause 17, wherein the mode filter has a lateral dimension that is less than, or equal to, a diameter of the primary optical aperture of the primary cavity.
19. The single mode TCC VCSEL of clause 17, further comprising at least a second mode filter positioned with respect to the secondary cavity to promote lasing of the selected wavelength or a secondary wavelength.
20. The single mode TCC VCSEL of clause 17, wherein the light emitted is capable of achieving a higher bandwidth in an optical communication system than if generated using only the first cavity or without the mode filter.
21. The single mode TCC VCSEL of clause 17, wherein the TCC VCSEL is configured to emit optical outputs as an excitable laser in a photonics neural network, wherein the TCC VCSEL emits the optical outputs from the primary cavity and the secondary cavity based on one or more communications received from a control module.
22. A laser device, comprising:
a vertical cavity surface-emitting laser (VCSEL) including a first cavity and an optical aperture to generate laser light to be emitted in a first direction;
one or more intracavity implantations positioned within the first cavity configured to confine current within the first cavity; and
one or more contacts configured to reduce electrical resistance within the VCSEL.
23. The laser device of clause 22, further comprising a mode filter positioned with respect to the first cavity to promote lasing of a selected wavelength of the laser light to be emitted.
24. The laser device of clause 22, further comprising one or more additional optical apertures positioned above and below an active region layer.
25. The laser device of clause 22, wherein the laser device includes only one p-DBR (distributed Bragg reflector) layer above the optical aperture.
26. The laser device of clause 22, wherein the contacts are comprised of metal and extend into the first cavity to enable additional mode filtering.
27. The laser device of clause 22, wherein the mode filter is positioned between one or more DBR layers within the first cavity.
28. The laser device of clause 22, wherein the mode filter is positioned on top of one or more dielectric layers.
29. The laser device of clause 21, further comprising:
a substrate comprising an upper layer of the VCSEL; and
one or more metal connections extending from the metal contacts to a heatsink positioned beneath the substrate.
30. The laser device of clause 22, further comprising:
a second cavity transversely coupled to the first cavity to allow at least a portion of the laser light, generated in the first cavity, to be reflected within both the first cavity and the second cavity, wherein the second cavity comprises one or more additional intracavity implantations positioned within the second cavity configured to confine current within the first cavity and one or more additional contacts configured to reduce electrical resistance within the VCSEL.
31. The laser device of clause 22, wherein the one or more contacts are further configured to promote lasing of the selected wavelength of the laser light to be emitted.
32. The laser device of clause 22 further comprising one or more p-DBR (distributed Bragg reflector) layers above the optical aperture.
33. The laser device of clause 22, wherein the optical aperture is an oxide aperture.
34. The laser device of clause 22, wherein the one or more contacts are positioned within the first cavity.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

In the scope of this application, the term arithmetic logic unit, or ALU, is used to refer to any computational logic circuit that processes operands to produce a result. For example, in the present document, the term ALU can refer to a floating point unit, a DSP, a tensor core, a shader core, a coprocessor, or a CPU.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU, DPU, QPU, or a plurality of parallel processing units (PPUs). A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A laser device, comprising:
a vertical cavity surface-emitting laser (VCSEL) including a first cavity and an optical aperture to generate laser light to be emitted in a first direction;
a second cavity transversely coupled to the first cavity to allow at least a portion of the laser light, generated in the first cavity, to be reflected within both the first cavity and the second cavity; and
a mode filter positioned with respect to the first cavity to promote lasing of a selected wavelength of the laser light to be emitted.

2. The laser device of claim 1, wherein the mode filter has a lateral dimension that is less than, or equal to, a diameter of the optical aperture of the first cavity.

3. The laser device of claim 1, further comprising:
a second mode filter positioned with respect to the second cavity to promote lasing of the selected wavelength or a secondary wavelength.

4. The laser device of claim 1, wherein the emitted laser light is capable of achieving a higher modulation bandwidth in an optical communication system than if generated using only the first cavity or without the mode filter.

5. The laser device of claim 1, further comprising:
at least one insulating region to electrically isolate the first cavity from the second cavity.

6. The laser device of claim 5, wherein the at least one insulating region is selected to control one or more feedback parameters from the second cavity, the one or more feedback parameters including at least a strength, a phase, or a time constant of feedback.

7. The laser device of claim 1, wherein at least one of the first cavity or the second cavity has a circular shape, an oval shape, a rectangular shape, or a square shape.

8. The laser device of claim 1, wherein the first cavity and the second cavity are formed together on a single wafer or substrate.

9. The laser device of claim 1, wherein the laser device is a transverse-coupled cavity, vertical cavity surface-emitting laser (TCC VCSEL) device.

10. An optical communication system, comprising:
an electrical input to receive an electrical signal;
a laser device to emit laser light to be propagated via an optical transmission mechanism; and
a modulator to modulate the laser light emitted from the laser device in order to encode data from the received electrical signal,
wherein the laser device includes:
a vertical cavity surface-emitting laser including a first cavity and an optical aperture to generate laser light to be emitted in a first direction;
a second cavity transversely coupled to the first cavity to allow at least a portion of the laser light, generated in the first cavity, to be reflected within both the first cavity and the second cavity; and
a mode filter positioned with respect to the first cavity to promote lasing of a selected wavelength of the light to be emitted.

11. The optical communication system of claim 10, wherein the mode filter has a lateral dimension that is less than, or equal to, a diameter of the optical aperture of the first cavity.

12. The optical communication system of claim 10, wherein the laser device further includes a second mode filter positioned with respect to the second cavity to promote lasing of the selected wavelength or a secondary wavelength.

13. The optical communication system of claim 10, wherein the emitted laser light is capable of achieving a higher modulation bandwidth in an optical communication system than if generated using only the first cavity or without the mode filter.

14. The optical communication system of claim 10, wherein the laser device further includes at least one insulating region to electrically isolate the first cavity from the second cavity.

15. The optical communication system of claim 14, wherein at least one insulating region is selected to control one or more feedback parameters from the second cavity, the one or more feedback parameters including at least a strength, phase, or time constant of feedback.

16. The optical communication system of claim 10, wherein the optical communication system is used with at least one of:
a system for performing simulation operations;
a system for performing simulation operations to test or validate autonomous machine applications;
a system for performing digital twin operations;
a system for performing light transport simulation;
a system for rendering graphical output;
a system for performing deep learning operations;
a system for performing generative AI operations using a large language model (LLM);
a system implemented using an edge device;
a system for generating or presenting virtual reality (VR) content;
a system for generating or presenting augmented reality (AR) content;
a system for generating or presenting mixed reality (MR) content;
a system incorporating one or more Virtual Machines (VMs);
a system implemented at least partially in a data center;
a system for performing hardware testing using simulation;
a system for performing generative operations using a language model (LM);
a system for synthetic data generation;
a collaborative content creation platform for 3D assets; or
a system implemented at least partially using cloud computing resources.

17. A single mode, transverse-coupled cavity, vertical cavity surface-emitting laser (TCC VCSEL), comprising:
a primary cavity including an active layer, a plurality of reflective layers, and a primary optical aperture to cause lasing of light of one or more wavelengths in a first direction;
a secondary cavity transversely coupled to the primary cavity to allow at least a portion of the light, generated in the primary cavity, to be reflected within both the primary cavity and the secondary cavity and to provide feedback to the primary cavity; and
a mode filter positioned with respect to the primary cavity to promote lasing of a selected wavelength of the light to be emitted.

18. The single mode TCC VCSEL of claim 17, wherein the mode filter has a lateral dimension that is less than, or equal to, a diameter of the primary optical aperture of the primary cavity.

19. The single mode TCC VCSEL of claim 17, further comprising at least a second mode filter positioned with respect to the secondary cavity to promote lasing of the selected wavelength or a secondary wavelength.

20. The single mode TCC VCSEL of claim 17, wherein the light emitted is capable of achieving a higher bandwidth in an optical communication system than if generated using only the primary cavity or without the mode filter.
